(19) United States
(12) Patent Application Publication
(10) Pub. No.: US 2019/0295822 A1
(43) Pub. Date: Sep. 26, 2019

(54) METHOD AND APPARATUS FOR PROVIDING RADICAL SPECIES TO A PROCESSING VOLUME OF A PROCESSING CHAMBER

(71) Applicant: Applied Materials, Inc., Santa Clara, CA (US)

(72) Inventors: Christopher S. OLSEN, Fremont, CA (US); Agus Sofian TJANDRA, Milpitas, CA (US); Eric Kihara SHONO, San Mateo, CA (US)

(21) Appl. No.: 16/359,845

(22) Filed: Mar. 20, 2019

Related U.S. Application Data
(60) Provisional application No. 62/645,496, filed on Mar. 20, 2018.

(51) Int. Cl. H01J 37/32; H01L 21/02

(52) U.S. Cl. CPC H01J 37/32357; H01J 2237/3321; H01L 21/0262; H01J 37/32449

(57) ABSTRACT

The present disclosure generally provides methods of providing at least metastable radical molecular species and, or, radical atomic species to a processing volume of a processing chamber during an electronic device fabrication process, and apparatus related thereto. In one embodiment, the apparatus is a gas injection assembly disposed between a remote plasma source and a processing chamber, where the gas injection assembly includes a body, a rigid dielectric liner disposed in the body, wherein the rigid dielectric liner defines a gas mixing volume, a first flange comprising a first mounting surface (to couple the gas injection assembly to a processing chamber), a second flange comprising a second mounting surface (to couple the gas injection assembly to the remote plasma source), and one or more gas injection ports formed through the body and the liner.

### CROSS-REFERENCE TO RELATED APPLICATIONS

This application claims priority to U.S. Provisional Application Ser. No. 62/645,496 filed on Mar. 20, 2018, which is herein incorporated by reference in its entirety.

### BACKGROUND

### Field

Embodiments described herein generally relate to the field of semiconductor device manufacturing processes, and more particularly, to methods of providing radical molecular species and, or, radical atomic species to a processing volume of a processing chamber during an electronic device fabrication process, and apparatus related thereto.

### Description of the Related Art

Remote plasma sources are commonly used to provide activated gases comprising radical species to a processing volume of a processing chamber, and to a surface of a substrate disposed in the processing volume, during the manufacturing of electronic devices, such as semiconductor devices on the substrate. In one such process, a processing gas is provided to the remote plasma source, a plasma is formed in the remote plasma source of the processing gas, and the plasma is flowed into the processing volume of the processing chamber where a surface of a substrate is exposed thereto. In some processes, such as nitridation processes where a film layer on the substrate is modified by the incorporation of Nitrogen therein, it may be desirable to provide a plasma activated radical molecular species, such as NH and, or, NH₂, to the processing volume and the surface of a substrate disposed therein. However, typically, when a molecular gas, for example NH₃, is provided to a remote plasma source and a plasma is formed therefrom, the resulting radicals in the plasma largely comprise radical atomic species, for example N and H, as controlling the remote plasma source process to produce radical molecular species, such as NH and, or, NH₂ in desirable quantities can be prohibitively difficult. Further, recombination of the radical atomic species (through gas phase collisions occurring in a delivery line between the remote plasma source and the processing chamber or in the processing chamber before reaching the substrate) is difficult to control and often produces undesired species, such as N₂, rather than the desired radical molecular species, such as NH and, or, NH₂, provided in the example.

In other processes, such as selective oxidation processes or hydrogen passivation processes, it is desirable to provide hydrogen radicals, herein atomic hydrogen, to the surface of a substrate. Unfortunately, conventional remote plasma sources are typically incompatible with plasmas formed of high concentrations of hydrogen, such as concentrations more than 20 atomic %, because higher concentrations of hydrogen ions in the plasma may result in damage to the dielectric surfaces of the remote plasma source. Therefore, atomic hydrogen is typically produced using a hot-wire source where molecular hydrogen is thermally dissociated into its radical (atomic) species through collision with a hot-wire filament, typically a tungsten filament. However, hot-wire dissociation of hydrogen can lead to undesirable metal contamination on the surface of the substrate, such as tungsten contamination, from the hot-wire filament.

Accordingly, what is needed in the art are improved methods, and apparatus related thereto, of providing radical molecular species and, or, radical atomic species to the processing volume of a processing chamber.

### SUMMARY

The present disclosure generally provides methods of providing radical molecular species and, or, radical atomic species to a processing volume of a processing chamber during an electronic device fabrication process, and apparatus related thereto.

In one embodiment a gas injection assembly features a metal body, a rigid dielectric liner disposed in the body, a first flange comprising a first mounting surface, a second flange comprising a second mounting surface, and one or more gas injection ports formed through the metal body and the rigid dielectric liner. Here, the rigid dielectric liner defines a mixing volume, a length of the gas injection assembly, measured along a longitudinal axis thereof between a plane of the first mounting surface and a plane of the second mounting surface, is between about 25 mm and about 150 mm, and the longitudinal axis of the gas injection assembly forms an angle with a longitudinal axis of a gas inlet port formed in a sidewall of a to be coupled processing chamber, and wherein the angle is between about 10° and about 70°.

In one embodiment a processing system includes a processing chamber, having a chamber body which defines a processing volume, a remote plasma source, and a gas injection assembly fluidly coupling the remote plasma source to the processing chamber. Here the gas injection assembly features a metal body, a rigid dielectric liner disposed in the body, a first flange comprising a first mounting surface, a second flange comprising a second mounting surface, and one or more gas injection ports formed through the metal body and the rigid dielectric liner. Here, the rigid dielectric liner defines a mixing volume, a length of the gas injection assembly, measured along a longitudinal axis thereof between a plane of the first mounting surface and a plane of the second mounting surface, is between about 25 mm and about 150 mm, and the longitudinal axis of the gas injection assembly forms an angle with a longitudinal axis of a gas inlet port formed in a sidewall of a to be coupled processing chamber, and wherein the angle is between about 10° and about 70°.

In one embodiment a method of processing a substrate includes positioning a substrate in a processing volume of a processing chamber, where the processing volume is in fluid communication with a remote plasma source via a gas injection assembly disposed therebetween, forming a plasma of a first gas in the remote plasma source, flowing the plasma into a mixing volume of the gas injection assembly, flowing a second gas to the mixing volume through one or more gas injection ports in fluid communication therewith, dissociating molecules of the second gas into radical species thereof, flowing the radical species into the processing volume of the processing chamber, and exposing the substrate to the radical species.

In another embodiment, a method of selectively oxidizing a surface of a substrate includes positioning a substrate in the processing volume of a processing chamber, where a surface of the substrate comprises a plurality of first features comprising silicon and a plurality of second features comprising metal, and heating the substrate to less than about 800° C. The method further includes forming a plasma of a first gas using a remote plasma source, where the remote plasma source is in fluid communication with the processing volume via a gas injection assembly disposed therebetween, and where the first gas comprises O₂ and less than about 20 atomic % H₂. The method further includes flowing the plasma into a mixing volume of the gas injection assembly, flowing a second gas comprising H₂ to the mixing volume through one or more gas injection ports in fluid communication therewith, and dissociating molecules of the second gas into radical species thereof to form an activated gas, where the activated gas comprises at least radical species of the first gas and radical species of the second gas. The method further includes flowing the activated gas into the processing volume of the processing chamber and exposing the surface of the substrate to the activated gas.

In another embodiment, a method of providing atomic hydrogen to a surface of a substrate includes positioning the substrate in a processing volume of a processing chamber, where the processing volume is fluidly coupled to a remote plasma source via a gas injection assembly disposed therebetween. The method further includes forming a plasma of a first gas using the remote plasma source, flowing the plasma into a mixing volume of the gas injection assembly, flowing a second gas comprising hydrogen into the mixing volume through one or more gas injection ports, dissociating the second gas into an activated gas comprising atomic hydrogen, flowing the activated gas into the processing volume of the processing chamber, and exposing a surface of the substrate to the activated gas.

In another embodiment, a method of providing ozone to a processing volume of a processing chamber includes forming a plasma of a first gas using a remote plasma source, where the first gas comprises O₂, and where the remote plasma source is fluidly coupled to the processing volume of the processing chamber via a gas injection assembly. The method further includes flowing the plasma into a mixing volume of the gas injection assembly, where the plasma comprises at least radical atomic oxygen species, flowing a second gas comprising O₂ into the mixing volume to form an activated gas comprising O₃; and flowing the activated gas into the processing volume of the processing chamber.

In another embodiment, a computer readable medium having instructions stored thereon for a method of processing a substrate is provided. The method includes positioning a substrate in a processing volume of a processing chamber, where the processing volume is in fluid communication with a remote plasma source via a gas injection assembly disposed therebetween, and forming a plasma of a first gas in the remote plasma source. The method further includes flowing the plasma into a mixing volume of the gas injection assembly, flowing a second gas to the mixing volume through one or more gas injection ports in fluid communication therewith, dissociating molecules of the second gas into radical species thereof, flowing the radical species into the processing volume of the processing chamber, and exposing the substrate to the radical species.

In another embodiment, a processing system includes a processing chamber, a remote plasma source, and a gas injection assembly fluidly coupling the remote plasma source to the processing chamber. The gas injection assembly includes a body, a dielectric liner disposed in the body, where the dielectric liner defines a mixing volume, a first flange coupling the gas injection assembly to a sidewall of a processing chamber, a second flange coupling the gas injection assembly to a remote plasma source, and one or more gas injection ports formed through the body and the liner.

In another embodiment, a gas injection assembly includes a metal body and a rigid dielectric liner disposed in the body, where the rigid dielectric liner defines a mixing volume. The gas injection assembly further includes a first flange comprising a first mounting surface, a second flange comprising a second mounting surface, and one or more gas injection ports formed through the body and the rigid dielectric liner.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-sectional view of a processing system, according to one embodiment.

FIG. 1B is a schematic cross-sectional view of the gas injection assembly shown in FIG. 1A taken along line 1B-1B, according to one embodiment.

FIG. 1C is a schematic cross-sectional view of the gas injection assembly of FIG. 1B taken along line 1C-1C, according to one embodiment.

FIG. 1D schematically illustrates the cross-sectional shape of an opening of a nozzle of the gas injection assembly of FIGS. 1A-1C, according to one embodiment.

FIG. 2 is a schematic cross-sectional view of a portion of a gas injection assembly, according to another embodiment.

FIG. 3 is a schematic cross-sectional view of a portion of a gas injection assembly, according to another embodiment.

FIG. 4 is a flow diagram of a method of processing a substrate, according to one embodiment.

FIG. 5 is flow diagram of a method of selectively oxidizing a silicon containing surface of a substrate, according to one embodiment.

FIG. 6 is a flow diagram of a method of providing atomic hydrogen to a surface of a substrate disposed in a processing volume of a processing chamber, according to one embodiment.

FIG. 7 is a flow diagram of a method of providing ozone (O₃) to the processing volume of a processing chamber, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to the field of semiconductor manufacturing processes, and more particularly, to methods of providing at least metastable radical molecular species and, or, radical atomic species to a processing volume of a processing chamber during an electronic device fabrication process, and apparatus related thereto. Herein, a metastable radical species is one that maintains its radical form before recombination into a non-radical species, under the processing conditions of the processing system, for more than about 10 milliseconds, such as more than about 0.1 seconds, or between about 10 milliseconds and about 3 seconds, for example between about 0.1 seconds and about 3 seconds.

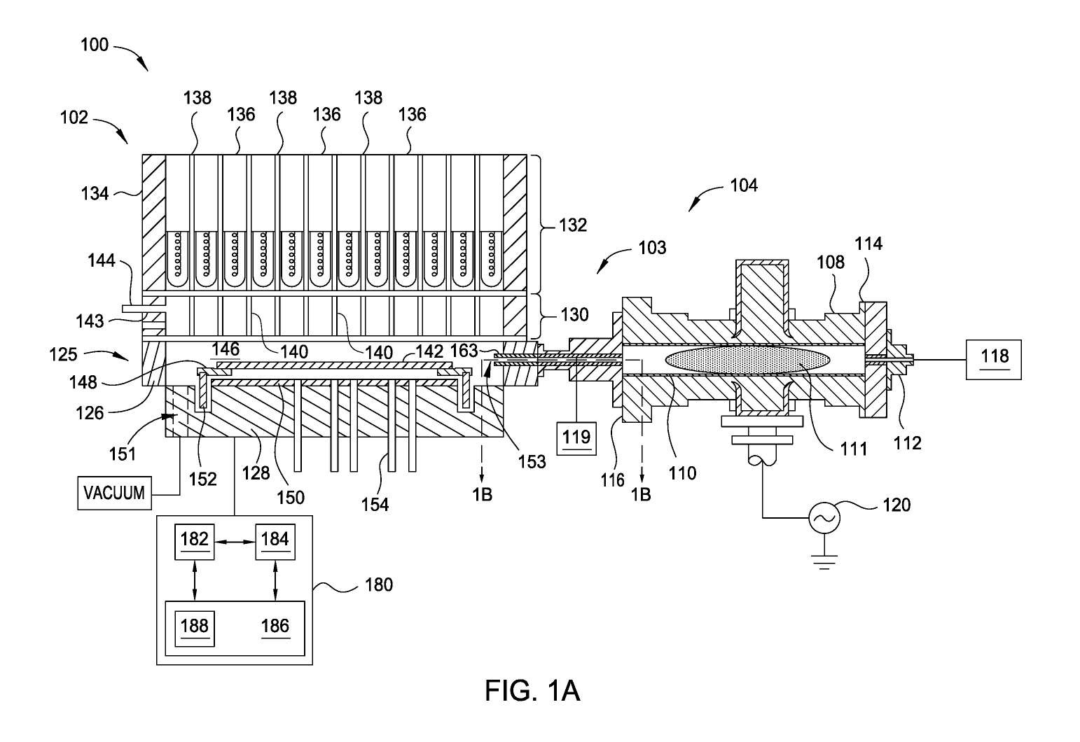

FIG. 1A is a schematic cross-sectional view of a processing system, according to one embodiment. The processing system 100 includes a processing chamber 102, a remote plasma source (RPS) 104, and a gas injection assembly 103 coupling the RPS 104 to the processing chamber 102. Herein, the processing chamber 102 is a rapid thermal processing (RTP) chamber, such as a rapid thermal anneal (RTA) chamber. In other embodiments, the processing chamber 102 is any other processing chamber where delivery of at least metastable radical molecular species and, or, radical atomic species to a processing volume is desired. For example, in other embodiments the processing chamber is plasma enhanced or plasma assisted deposition chamber, such as a plasma enhanced chemical vapor deposition (PECVD) chamber or a plasma enhanced atomic layer deposition chamber (PEALD).

A controller 180 coupled to the processing system 100 is used to control the operation of the processing chamber 102, the RPS 104, and the gas flow into the gas injection assembly 103 disposed therebetween. The controller 180 generally includes a central processing unit (CPU) 182, a memory 186, and support circuits 184 for the CPU 182. The controller 180 may control the process system 100 directly, or via other computers and, or, controllers (not shown) coupled to the processing chamber 102, the RPS 104, and, or, the gas injection assembly 103. The controller 180 herein is any form of a general-purpose computer processor that is used in an industrial setting for controlling various chambers and sub-processors thereon or therein. The memory 186, or computer-readable medium, is one or more of readily available memory such as random access memory (RAM), read only memory (ROM), floppy disk, hard disk, flash drive, or any other form of digital storage, local or remote. The support circuits 184 are coupled to the CPU 182 for supporting the processor in a conventional manner. The support circuits 184 include cache, power supplies, clock circuits, input/output circuitry and subsystems, and the like. Typically, substrate processing parameters are stored in the memory 186 as a software routine 188 that is executed or invoked to turn the controller 180 into a specific purpose controller to control the operations of the process system 100. The controller 180 is configured to perform any of the methods described herein.

The processing chamber 102 includes a chamber base 125, a lamp assembly 132, and a window assembly 130 coupled to the lamp assembly 132. The chamber base includes a base wall 128 and one or more first sidewalls 126. The base wall 128, the one or more first sidewalls 126, and the window assembly 130 define a processing volume 146. The window assembly 130 is disposed between the processing volume 146 and the lamp assembly 132. Herein, the lamp assembly 132, enclosed by one or more second sidewalls 134, includes a plurality of lamps 136 each disposed in a respective tube 138. The window assembly 130 includes a plurality of light pipes 140, where each of the plurality of light pipes 140 is aligned with a respective tube 138 of the lamp assembly 132 so that the radiant thermal energy provided by the plurality of lamps 136 is directed to a substrate 142 disposed in the processing volume 146.

In some embodiments, one or more respective volumes in the plurality of light pipes 140 are maintained at sub-atmospheric conditions using one or more vacuum exhaust pumps (not shown) in fluid communication therewith through an opening 144 formed in one of the one or more second sidewalls 134. In some embodiments, the window assembly 130 further includes a conduit 143 disposed therein for circulating a cooling fluid from a cooling fluid source (not shown) between the plurality of light pipes 140. Herein, the processing volume 146 is fluidly coupled to a chamber exhaust, such as to one or more dedicated vacuum pumps, through one or more exhaust ports 151. The chamber exhaust maintains the processing volume 146 at sub-atmospheric conditions and evacuates processing and other gases therefrom.

A support ring 148 disposed in the processing volume 146 is used to support a substrate 142 during the processing thereof. The support ring 148 is coupled to a rotatable cylinder 152 which is used to rotate the support ring 148 about a vertical axis thereof to facilitate uniform heating of the substrate 142. In some embodiments, the cylinder 152 is levitated and rotated by a magnetic levitation system (not shown). A reflector plate 150 disposed on the base wall 128 in the processing volume 146 is used to reflect energy to a non-device surface of the substrate 142 to further facilitate uniform heating of the substrate 142. Typically, one or more temperature sensors, such as pyrometers 154 disposed through the base wall 128 and further disposed through the reflector plate 150, are used to monitor the temperature of the substrate 142 during the processing thereof. An activated gas, formed according to embodiments described herein, flows into the processing volume 146 of the processing chamber 102 through an inlet port 153, disposed through one of the one or more sidewalls 126, which is fluidly coupled to the gas injection assembly 103. In some embodiments, the inlet port 153 is defined by a nozzle, such as nozzle 163. Herein, the activated gas comprises molecular and, or, atomic species, at least metastable radical molecular and, or, radical atomic species, or combinations thereof.

The RPS 104 herein is coupled to a microwave power supply 120 which is used to ignite and maintain a plasma 111 therein. In other embodiments, the RPS 104 comprises an inductively coupled plasma (ICP) source, a transformer coupled plasma (TCP source), or a capacitively coupled plasma (CCP source). In some other embodiments, the RPS is coupled to an RF power supply. The RPS 104 includes an RPS body 108 disposed about a tube 110 in which the plasma 111 is formed. Typically, the tube 110 is formed of a dielectric material, such as SiO₂, Al₂O₃, quartz, or combinations thereof. The RPS body 108 includes a first end 114 coupled to an inlet 112 which is in fluid communication with one or more first gas sources 118 and a second end 116, distal from the first end 114, coupled to the gas injection assembly 103. The gas injection assembly 103 is further described in FIG. 1B.

FIG. 1B is a schematic sectional view of a portion of the gas injection assembly 103 taken along line 1B-1B of FIG. 1A. Herein, the gas injection assembly 103 includes a body 170 formed of a metal, such as stainless steel, a rigid low recombination dielectric liner 173, such as quartz or sapphire, a first flange 171 configured to couple the gas injection assembly 103 to one of the one or more sidewalls of a processing chamber, such as the one of the one or more sidewalls 126 of the processing chamber 102 described in FIG. 1A, a second flange 172 configured to couple the gas injection assembly 103 to an RPS, such as the RPS 104 described in FIG. 1A, and one or more gas injection ports 174 formed through the body 170 and the liner 173. In some embodiments, the gas injection assembly 103 has a length L(1), measured along its longitudinal axis A between a mounting surface plane of the first flange 171 and a mounting surface plane of the second flange 172, where the length L(1) is between about 25 mm and about 150 mm, such as between about 50 mm and about 100 mm, such as between about 75 mm and about 100 mm. In some embodiments, the liner 173, coaxially disposed in the body 170 about the longitudinal axis A and protecting the metal body thereof from the activated species in the plasma, defines a mixing volume 175 having a diameter D(1) of between about 20 mm and about 60 mm, such as between about 25 mm and about 50 mm. Herein, the nozzle 163, defining the inlet port 153, includes a first opening 153a proximate to, and in fluid communication with, the mixing volume 175, and a second opening 153b distal from the first opening 153a, where the second opening 153b is disposed in, and in fluid communication with, the processing volume 146 of the processing chamber 102.

Typically, the first opening 153a of the nozzle 163 has a generally circular cross-sectional shape (orthogonal to the longitudinal axis B) and the second opening 153b of the nozzle 163 has a generally oval or rectangular shape, such as the slit shape shown in FIG. 1D having a width W(1) and a height H. Herein, a ratio of the flow cross-sectional area of the mixing volume 175 (where the flow cross-sectional area of the mixing volume 175 is orthogonal to the longitudinal axis A) and the flow cross-sectional area of the inlet port 153 at the second opening 153b (which is orthogonal to longitudinal axis B) is between about 1:5 and about 1:10. Expanding the flow cross-sectional area for gases flowing into the processing volume 146 reduces recombination of radical molecular and, or, radical atomic species, desirably resulting in a higher radical concentration and flux at the surface of the substrate when compared to nozzles that do not expand the flow cross-sectional area between the mixing volume 175 and the processing volume 146.

In a typical process, a plasma 111 formed in the RPS 104 flows into the mixing volume 175 of the gas injection assembly 103 where radicals and, or, ions, for example argon ions, from the plasma collide with the molecular species of one or more second gases, for example H₂, injected into the mixing volume 175 through the gas injection ports 174. The radicals and, or, ions provided by the plasma 111 have sufficient energy to dissociate the molecular species, through collision therewith, into an activated gas comprising at least metastable radical molecular species and, or, radical atomic species, for example atomic hydrogen. Herein, the one or more second gases are provided to the mixing volume 175 through one or more gas injection ports 174, where the one or more gas injection ports 174 are fluidly coupled to a second gas source 119.

Each of the one or more gas injection ports 174 comprise an opening formed through the body 170 and further through the liner 173. In some embodiments, a diameter D(2) of the one or more gas injection ports 174 is between about 0.5 mm and about 6 mm, such as between about 1 mm and about 6 mm, such as between about 2 mm and about 5 mm, for example between about 2 mm and about 4 mm. Typically, the one or more gas injection ports 174 are located at a distance L(2), as measured along the longitudinal axis A from a mounting surface plane of the first flange 171 to one or more longitudinal axis E of the one or more respective gas injection ports 174. In some embodiments, the distance L(2) is between about 20 mm and about 80 mm, such as between about 30 mm and about 60 mm, or less than about 80 mm, such as less than about 60 mm. Typically, a longitudinal axis E of the one or more gas injection ports forms an angle ϕ with the longitudinal axis A of the gas injection ports where the angle ϕ is substantially 90°. In other embodiments, the angle ϕ is less than about 90° so that the second gas as introduced through the gas injection port 174 is generally flowing in the downstream direction towards the gas inlet port 153 of the processing chamber 102 and not upstream towards the RPS 104.

Typically, the longitudinal axis A of the gas injection assembly 103 intersects with a longitudinal axis B of the gas inlet port 153 (disposed through one of the one or more sidewalls of a to be coupled processing chamber) at an angle θ of between about 0° (i.e., co-linear) and about 80°, such as between about 10° and about 70°, such as between about 20° and about 70°, or between about 10° and about 45°, for example between about 20° and about 45°. In some embodiments, the longitudinal axis A of the gas injection assembly 103 and a longitudinal axis C of the RPS 104 form an angle α of less than about 45°, such as less than about 30°, such as less than about 20°, for example less than about 10°, or between about 0° and or about 20°, for example between about 10° and about 20°.

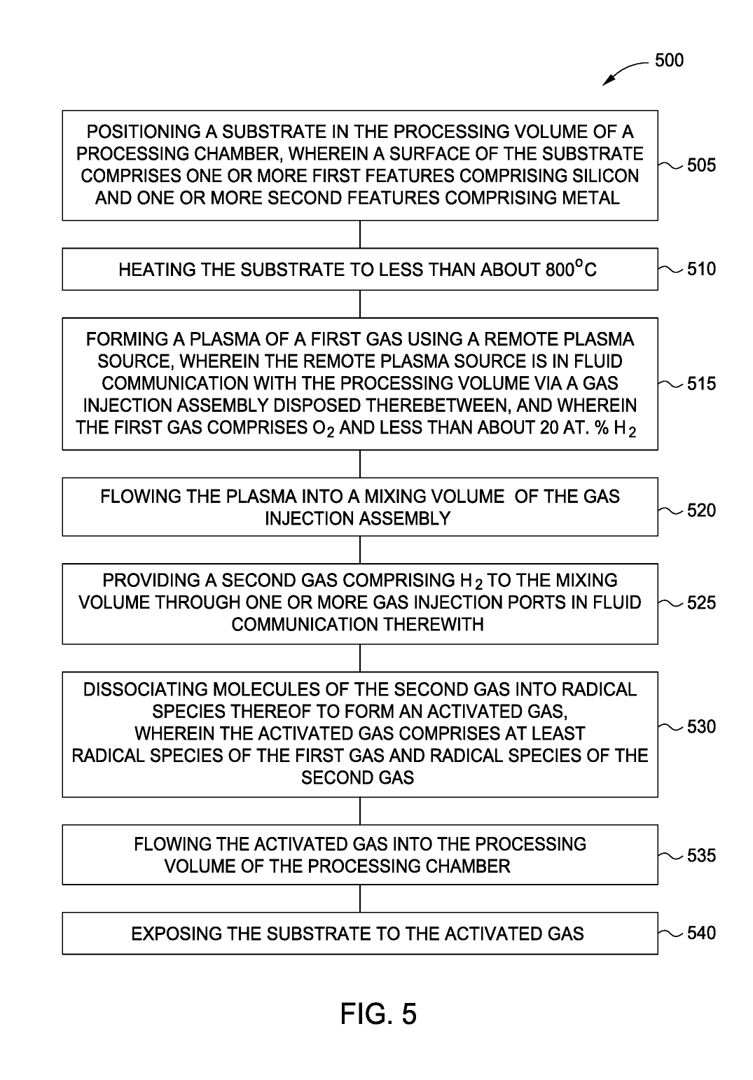

In some embodiments, the longitudinal axis C of the RPS 104 and the longitudinal axis A of the gas injection assembly 103 are substantially co-linear or are substantially parallel. Providing an angle θ, and, or, an angle α of more than about 0° promotes recombination of ions with electrons or other charged particles through collision therebetween as the ions lose their momentum through collisions when hitting the interior surfaces of the inlet port 153. This substantially reduces the ion density of the activated gas as it flows into the processing volume. Because of the high chemical activity of ions compared to radicals, low ion density in the activated gas provided to the processing volume of a processing chamber is desirable in some processes, such as the selective oxidation process set forth in FIG. 5.

FIG. 1C is a schematic cross-sectional view of the gas injection assembly 103 taken along lines 1C-1C of FIG. 1B, where the gas injection assembly comprises a plurality of, here two, gas injection ports 174a,b. Herein, a longitudinal axis E of a first gas injection port 174a is offset from a second longitudinal axis E′ of a second gas injection port 174b so that gases flowing from each of the gas injection ports 174a,b are not introduced into the mixing volume 175 directly opposite of one another (not collinear) so that gases introduced therefrom do not undesirably collide head on in the mixing volume 175 which could create an undesirable hot spot and result in less efficient mixing with the plasma flowing therethrough. As shown, the gas injection ports 174a,b have a substantially circular cross-sectional shape.

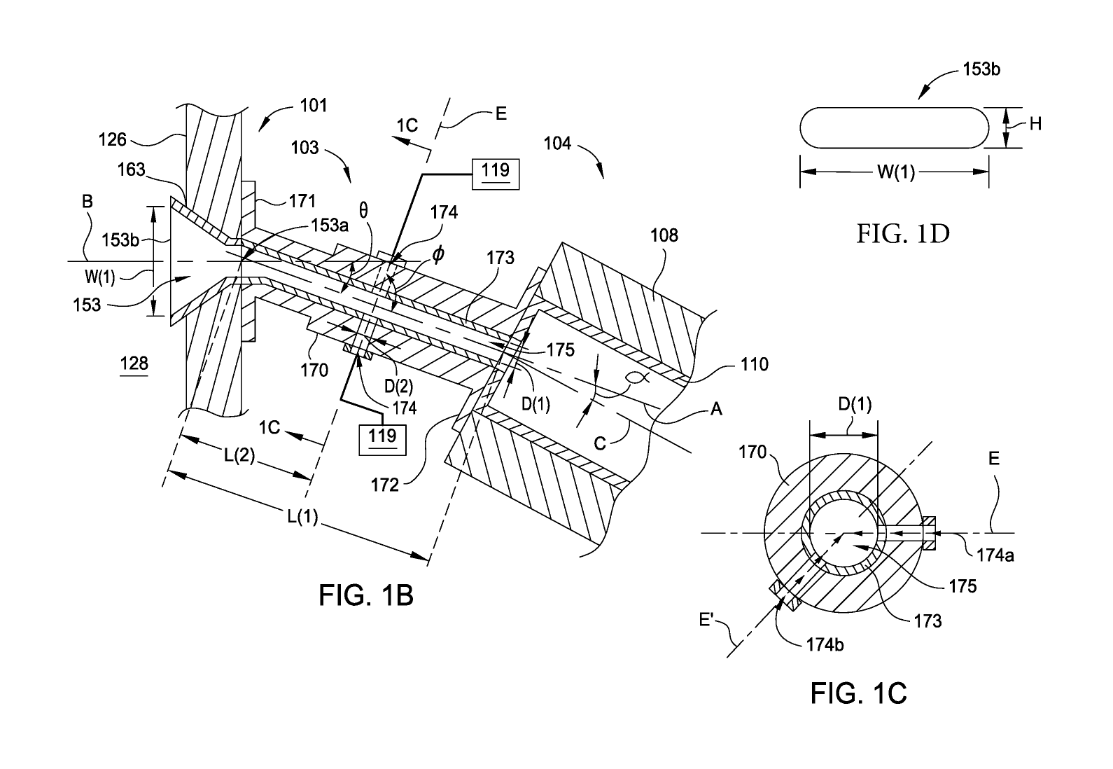

FIG. 2 is a schematic cross-sectional view of a portion of a gas injection assembly 203, according to another embodiment. The gas injection assembly 203 is substantially similar to the gas injection assembly 103 described in FIGS. 1A-1C except that one or more gas injection ports 274 disposed through the body 170 and the liner 173 have a substantially slit cross-sectional shape at a first opening 274a in the liner 173 and a substantially circular cross-sectional shape at a second opening 274b in a surface of the body 170. Herein, the one or more first openings 274a have a length L(3) to width W(2) ratio, of more than 1:1, such as more than 2:1, for example more than about 3:1. In some embodiments, the width W(2) is between about 0.5 mm and about 6 mm, such as between about 1 mm and about 5 mm, for example between about 1 mm and about 4 mm. In this embodiment, the one or more first openings 274a of the one or more gas injection ports 274 are substantially parallel, along their length L(3), to the longitudinal axis A of the gas injection assembly 203. In other embodiments, the one or more first openings 274a of the one or more gas injection ports 274 are substantially orthogonal to the longitudinal axis A along their length L(3).

In other embodiments, the first openings 274a of the one or more gas injection ports 274 are of any other orientation to the longitudinal axis A. Typically, the cross-sectional shape of the gas injection port 274 gradually changes from a substantially circular cross-sectional shape (orthogonal to the longitudinal axis E) at the second opening 274b to the substantially slit cross-sectional shape at the first opening 274a to direct gas flow therethrough to ribbon like flow as in enters the mixing volume 175. In other embodiments, the one or more gas injection ports 274 maintain a substantially slit cross-sectional shape from the second opening 274b to the first opening 274a and substantially the same cross-sectional opening area therethrough.

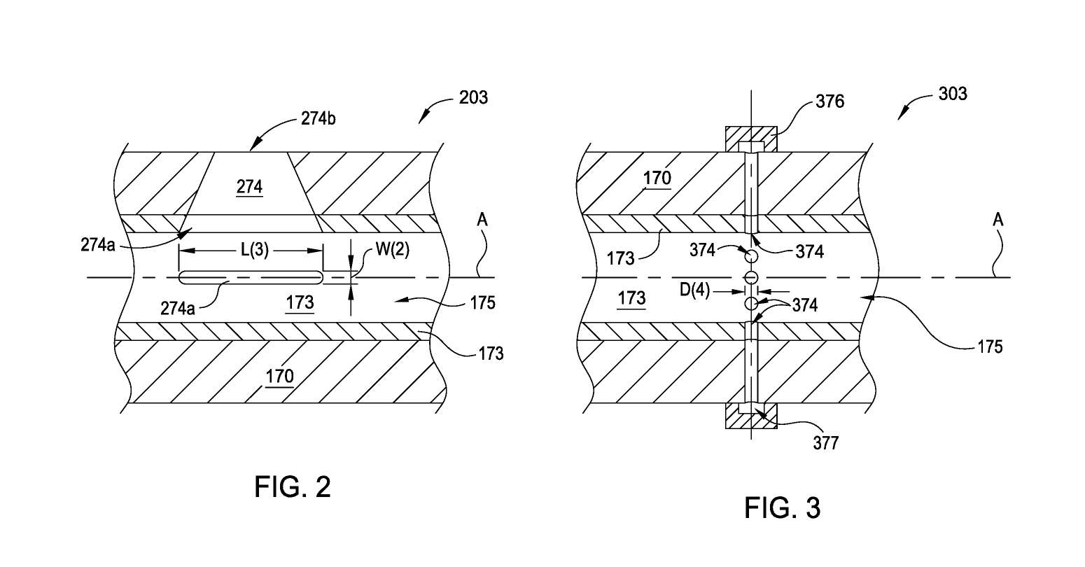

FIG. 3 is a schematic cross-sectional view of a portion of a gas injection assembly 303, according to another embodiment. The gas injection assembly 303 is substantially similar to the gas injection assembly 103 described in FIGS. 1A-1C except that processing gases are delivered to the mixing volume 175 through a plurality of openings 374 formed through the liner 173 and the body 170, where the plurality of openings 374 are in fluid communication with a annular passage 337 disposed in an annular ring 376 coupled to the body 170 and concentrically disposed about a circumference thereof. In some embodiments, each of the plurality of openings 374 have a diameter D(4) between about 0.1 mm and about 5 mm, such as between about 0.5 mm and about 4 mm, or between about 0.5 mm and about 4 mm, for example between about 1 mm and about 4 mm.

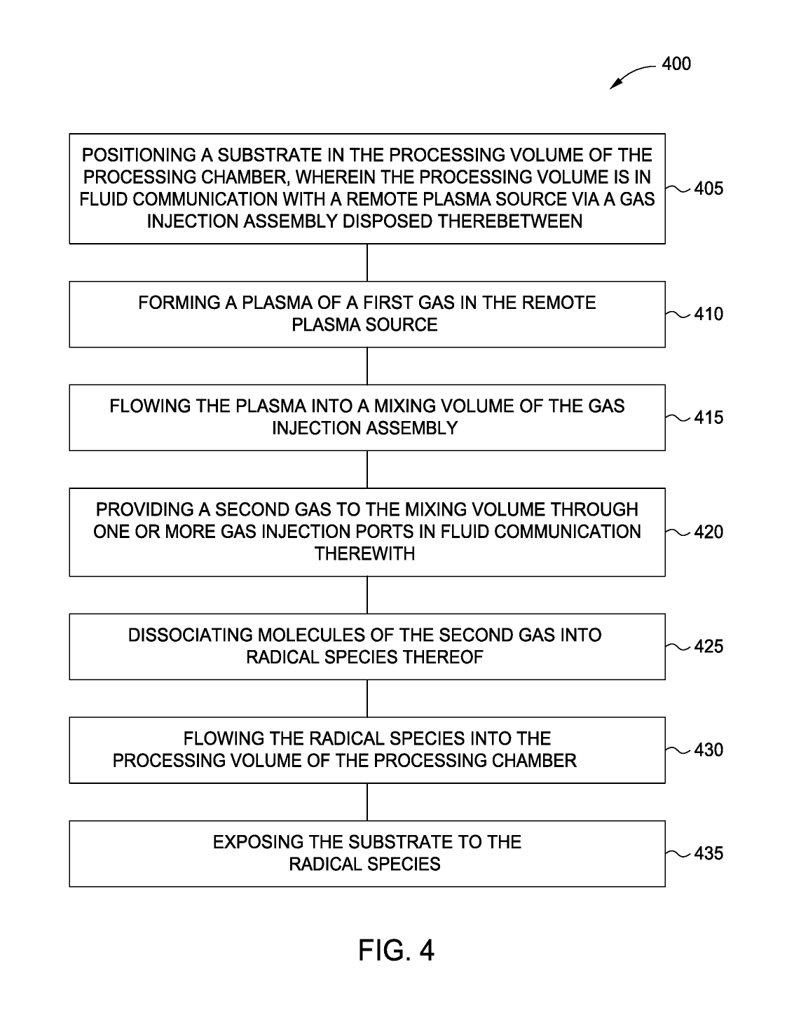

FIG. 4 is a flow diagram of a method of providing at least metastable radical molecular and, or, radical atomic species to the processing volume of a processing chamber. At activity 405 the method 400 includes positioning a substrate in the processing volume of the processing chamber, where the processing volume is in fluid communication with a remote plasma source via a gas injection assembly disposed therebetween. In some embodiments, the processing chamber is a rapid thermal processing (RTP) chamber, such as the processing chamber 102 described in FIG. 1A.

At activities 410 and 415 the method 400 respectively includes forming a plasma of a first gas in the remote plasma source and flowing the plasma into a mixing volume of a gas injection assembly, such as the gas injection assemblies 103, 203, or 303 described in FIGS. 1-3. At activity 420 the method 400 includes flowing a second gas to the mixing volume of the gas injection assembly through one or more gas injection ports in fluid communication therewith.

At activity 425 the method 400 includes dissociating molecules of the second gas into molecular and, or, radical atomic species thereof. Herein, dissociating molecules of the second gas into the radical species thereof comprises colliding radicals, ions, and other charged particles of the plasma with molecules of the second gas in the mixing volume of the gas injection assembly.

At activity 430 the method 400 includes flowing the radical species into the processing volume of the processing chamber. At activity 435 the method includes exposing the substrate to the radical species. In some embodiments, the method 400 further includes heating the substrate to a processing temperature between about 500° C. and about 1100° C., such as between about 500° C. and about 1000° C., or less than about 1000° C., such as less than about 900° C., for example less than about 850° C. In some embodiments of the method 400, heating the substrate includes directing radiant energy towards a device side surface thereof.

In one embodiment, the device side surface of the substrate in the method 400 includes a dielectric layer, such as SiO₂, SiON, a high-K dielectric, or combinations thereof. High-K dielectric layers herein include aluminum-(Al), hafnium-(Hf), lanthanum-(La), or zirconium-(Zr) based oxides, oxynitrides, and, or, silicon nitrides (SiₓN_{y}), in single or layered structures (e.g., a SiO₂/high-k/SiO₂). In some embodiments, the second gas comprises a nitrogen containing gas, such as NH₃, the radical species comprise N, NH, NH₂, or combinations thereof, and exposing the substrate to the radical species includes exposing the dielectric layer to the radical species. In some embodiments, the first gas comprises a noble gas, such as argon, helium, neon, xenon, krypton, or a combination thereof. In some embodiments, the first gas comprises a noble gas, N₂, or a combination thereof.

FIG. 5 is flow diagram of a method of selectively oxidizing a silicon containing surface of a substrate, according to one embodiment. At activity 505 the method 500 includes positioning a substrate in the processing volume of a processing chamber, where a surface of the substrate comprises a plurality of features comprising silicon, such as amorphous silicon, polysilicon, and, or, crystalline silicon, and a plurality of non-silicon features, such as features comprising metal, such as tungsten features.

At activity 510 the method 500 includes heating the substrate by directing radiant energy theretowards. Herein, the substrate is heated to a temperature of less than about 1000° C., such as less than about 900° C., for example less than about 850° C., or less than about 800° C. In some embodiments, the substrate is heated to and, or, maintained at a temperature between about 550° C. and about 650° C., for example about 600° C. In some embodiments, the processing volume is maintained at a pressure less than about 5 Torr, such as less than about 3 Torr, for example about 1.5 Torr.

At activity 515 the method 500 includes forming a plasma of a first gas using a remote plasma source. Herein, the first gas comprises O₂ and H₂ where the ratio of H₂ molecules to O₂ molecules is between about 1:5 and about 1:4. In some embodiments, a ratio of H₂ to O₂ is less than about 1:4, such as less than about 1:5, less than about 1:10. In some embodiments, the first gas is substantially free of H₂. In some embodiments, the first gas further comprises an inert gas, such as argon, helium, krypton, or a combination thereof.

At activity 520 the method 500 includes flowing the plasma into a mixing volume of a gas injection assembly disposed between the remote plasma source and the processing volume of the processing chamber.

At activity 525 the method 500 includes flowing a second gas comprising H₂ into the mixing volume through one or more gas injection ports formed in the body and liner of the gas injection assembly. Herein, the ions, radicals, and, or, other charged particles of the plasma collide with the molecules of the second gas to dissociate the molecules of the second gas into radical molecular species and, or, radical atomic species thereof. The plasma and the radical species of the second gas form an activated gas. Herein, by addition of sufficient H₂ to the stream of activated O, and optionally H, coming from the remote plasma source, the atomic ratio of hydrogen to oxygen in the mixing volume and entering the processing chamber is more than about 3:1, such as more than about 4:1, such as more than about 5:1, or between about 4:1 and about 10:1. Beneficially, the addition of hydrogen to the stream of activated O, and optionally H, coming from the remote plasma source allows for increased activated hydrogen concentration from less than an atomic ratio of less than 1:4 (H:O) required to prevent damage to the RPS to more than about 3:1 in the activated gas flowing into the processing volume of the processing chamber.

At activity 530 the method 500 includes flowing the activated gas into the processing volume of the processing chamber.

At activity 535 the method 500 includes exposing the substrate to the activated gas. In some embodiments, exposing the substrate to the activated gas oxidizes the plurality of features comprising silicon to form SiO₂. In some embodiments of the method 500, exposing the substrate to the activated gas oxidizes the plurality of features comprising silicon and does not oxidize the plurality of non-silicon features, such as metal features.

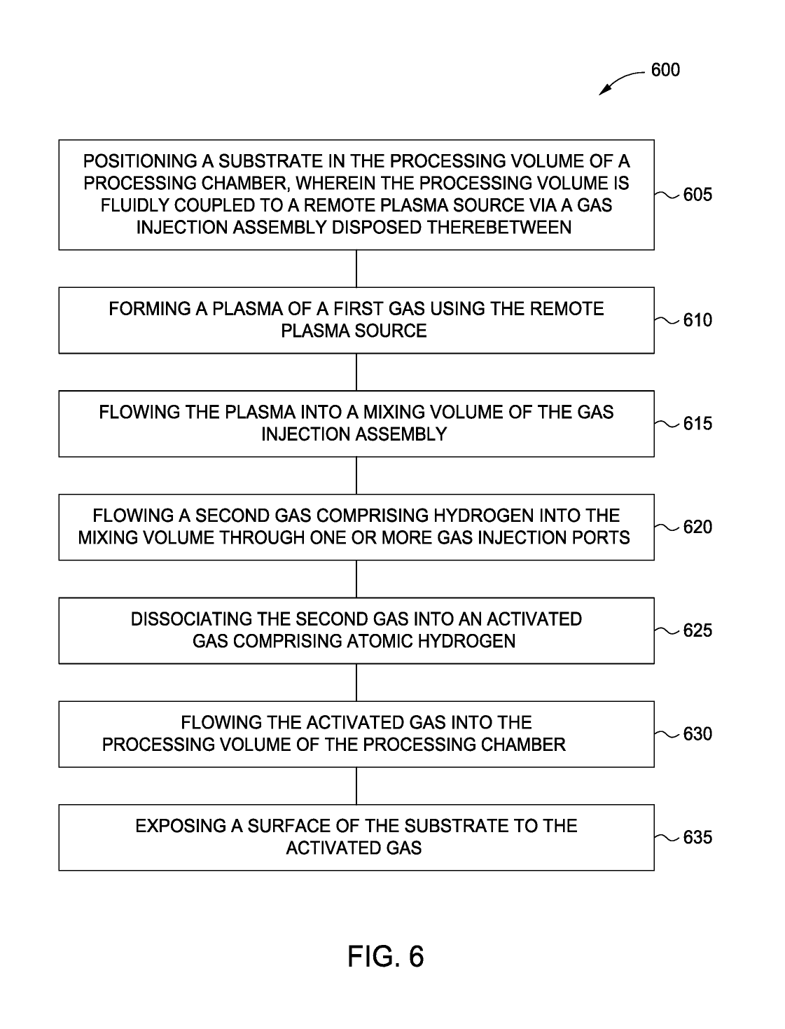

FIG. 6 is a flow diagram of a method of providing atomic hydrogen to a surface of a substrate disposed in a processing volume of a processing chamber, according to one embodiment. At activity 605 the method 600 includes positioning a substrate in the processing volume of a processing chamber, wherein the processing volume is fluidly coupled to a remote plasma source via a gas injection assembly disposed therebetween. At activity 610 the method 600 includes forming a plasma of a first gas using the remote plasma source. Herein, the first gas comprises one or more noble gases, such as argon, helium, neon, xenon, krypton, or a combination thereof. In one embodiment, the first gas comprises argon. At activity 615 the method 600 includes flowing the plasma into a mixing volume of the gas injection assembly. At activity 620 the method 600 includes flowing a second gas comprising hydrogen, such as H₂, into the mixing volume through one or more gas injection ports. At activity 625 the method includes dissociating the second gas into at least metastable radical molecular and, or, radical atomic species thereof, such as atomic hydrogen, to form an activated gas. At activity 630 the method includes flowing the activated gas into the processing volume of the processing chamber. At activity 635 the method 600 includes exposing a surface of the substrate to the activated gas. In some embodiments, exposing the surface of the substrate to the activated gas cleans and, or, hydrogen passivates the surface of the substrate before epitaxial growth of a layer thereon, such as an epitaxially grown silicon layer.

In another embodiment, the method 600 further includes sequentially and cyclically exposing the substrate to a first precursor gas and a second precursor gas, herein the activated gas, to form a material layer thereon. In this embodiment, the method 600 includes at least one cycle of exposing the substrate to the first precursor gas, where exposing the substrate to the first precursor gas comprises reacting the substrate surface with the first precursor gas to form a first layer, and exposing the substrate to the activated gas to form a second layer, where exposing the substrate to the activated gas comprises reacting the first layer with the activated gas to form a second layer, and where the second layer is hydrogen terminated. Herein, the activated gas is formed by forming a plasma of a first gas, for example argon, using the remote plasma source, flowing the plasma into a mixing volume of a gas injection assembly, flowing a second gas comprising hydrogen, such as H₂, into the mixing volume through one or more gas injection ports, and dissociating the second gas into at least metastable radical molecular and, or, radical atomic species thereof, such as atomic hydrogen, to form an activated gas. In some embodiments, the method 600 comprises a plurality of sequential cycles of exposing the substrate to the first precursor gas and exposing the substrate to the activated gas.

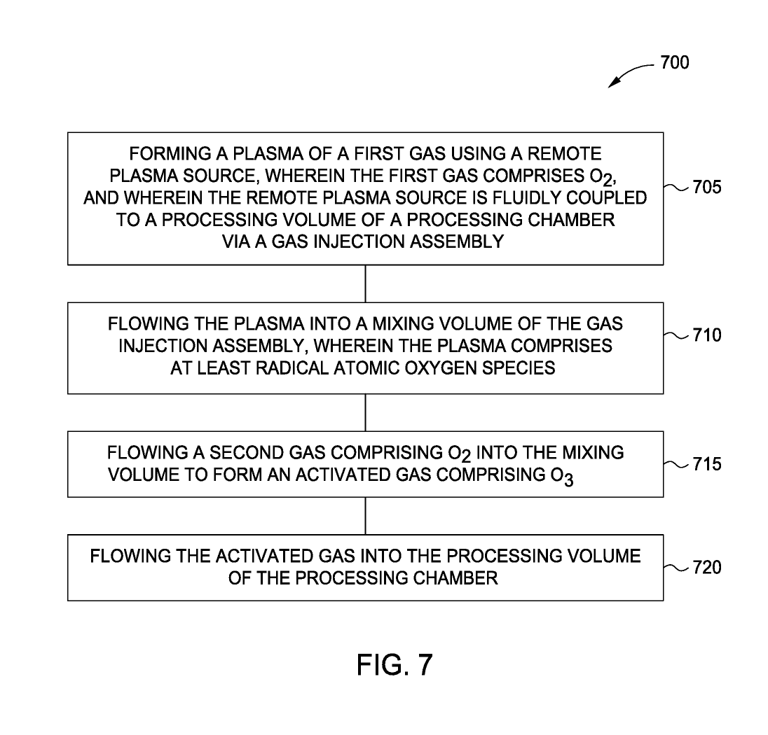

FIG. 7 is a flow diagram of a method of providing ozone (O₃) to the processing volume of a processing chamber, according to one embodiment. At activity 705 the method 700 includes forming a plasma of a first gas using a remote plasma source, where the first gas comprises O₂, and where the remote plasma source is fluidly coupled to a processing volume of a processing chamber via a gas injection assembly, such as any of the gas injection assemblies described in FIGS. 1-3. At activity 710 the method 700 includes flowing the plasma into a mixing volume of the gas injection assembly, herein the plasma comprises at least radical atomic oxygen species. At activity 715 the method 700 includes flowing a second gas comprising O₂ molecules into the mixing volume to form an activated gas comprising O₃. Typically, forming O₃ from the radical atomic oxygen species and the O₂ is a result of gas phase collisions therebetween. At activity 720 the method 700 includes flowing the activated gas into the processing volume of the processing chamber. In some embodiments, the method 700 further includes exposing a surface of a substrate to the activated gas, where the substrate is disposed in the processing volume of the processing chamber.

Further embodiments include a computer readable medium having instructions for any of the methods described in FIGS. 4-7 stored thereon.

While the foregoing is directed to embodiments of the present disclosure, other and further embodiments of the disclosure may be devised without departing from the basic scope thereof, and the scope thereof is determined by the claims that follow.

1. A gas injection assembly, comprising
a metal body;
a rigid dielectric liner disposed in the metal body, wherein the rigid dielectric liner defines a mixing volume;
a first flange comprising a first mounting surface;
a second flange comprising a second mounting surface; and
one or more gas injection ports formed through the metal body and the rigid dielectric liner, wherein
a length of the gas injection assembly, measured along a longitudinal axis thereof between a plane of the first mounting surface and a plane of the second mounting surface, is between about 25 mm and about 150 mm, and
the longitudinal axis of the gas injection assembly forms an angle with a longitudinal axis of a gas inlet port formed in a sidewall of a to be coupled processing chamber, and wherein the angle is between about 10° and about 70°.

2. The gas injection assembly of claim 1, wherein the rigid dielectric liner comprises quartz, sapphire, or a combination thereof.

3. The gas injection assembly of claim 1, wherein the rigid dielectric liner, coaxially disposed in the metal body, defines a mixing volume having an inner diameter of between about 20 mm and about 60 mm.

4. The gas injection assembly of claim 3, wherein at least one of the one or more gas injection ports is located between about 20 mm and about 80 mm from the first mounting surface.

5. The gas injection assembly of claim 4, wherein the one or more gas injection ports have a diameter of between about 0.5 mm and about 6 mm.

6. A processing system, comprising:
a processing chamber, having a chamber body which defines a processing volume;
a remote plasma source; and
a gas injection assembly fluidly coupling the remote plasma source to the processing chamber, wherein the gas injection assembly comprises:
a metal body;
a rigid dielectric liner disposed in the metal body, wherein the rigid dielectric liner defines a mixing volume;
a first flange comprising a first mounting surface;
a second flange comprising a second mounting surface; and
one or more gas injection ports formed through the metal body and the rigid dielectric liner, wherein
a length of the gas injection assembly, measured along a longitudinal axis thereof between a plane of the first mounting surface and a plane of the second mounting surface, is between about 25 mm and about 150 mm, and
the longitudinal axis of the gas injection assembly forms an angle with a longitudinal axis of a gas inlet port formed in a sidewall of a to be coupled processing chamber, and wherein the angle is between about 10° and about 70°.

7. The processing system of claim 6 wherein the rigid dielectric liner comprises quartz, sapphire, or a combination thereof.

8. The processing system of claim 6, wherein at least one of the one or more gas injection ports is located between about 20 mm and about 80 mm from the first mounting surface.

9. The processing system of claim 8, wherein the one or more gas injection ports have a diameter of between about 0.5 mm and about 6 mm.

10. The processing system of claim 6, wherein the rigid dielectric liner, coaxially disposed in the metal body, defines a mixing volume having an inner diameter of between about 20 mm and about 60 mm.

11. The processing system of claim 10, further comprising a nozzle defining an inlet port into the processing volume, wherein
the nozzle defines a first opening proximate to, and in fluid communication with, the mixing volume and a second opening distal from the first opening, and
a ratio of a flow cross-sectional area of the mixing volume and a flow cross-sectional area of the inlet port at the second opening is between about 1:5 and about 1.10.

12. The processing system of claim 6, further comprising computer readable medium having instructions stored thereon for a method of processing a substrate, the method comprising:
positioning a substrate in the processing volume of the processing chamber, wherein the processing volume is in fluid communication with a remote plasma source via a gas injection assembly disposed therebetween;
forming a plasma of a first gas in the remote plasma source;
flowing the plasma into a mixing volume of the gas injection assembly;
flowing a second gas to the mixing volume through one or more gas injection ports in fluid communication therewith;
dissociating molecules of the second gas into radical species thereof;
flowing the radical species into the processing volume of the processing chamber; and
exposing the substrate to the radical species.

13. The processing system of claim 12, wherein the method further comprises heating the substrate to a temperature between about 500° C. and about 1100° C.

14. The processing system of claim 13, wherein heating the substrate comprises directing radiant energy towards a device side surface thereof.

15. A method of processing a substrate, comprising:
positioning a substrate in a processing volume of a processing chamber, wherein the processing volume is in fluid communication with a remote plasma source via a gas injection assembly disposed therebetween;
forming a plasma of a first gas in the remote plasma source;
flowing the plasma into a mixing volume of the gas injection assembly;
flowing a second gas to the mixing volume through one or more gas injection ports in fluid communication therewith;
dissociating molecules of the second gas into radical species thereof;
flowing the radical species into the processing volume of the processing chamber; and
exposing the substrate to the radical species.

16. The method of claim 15, wherein the first gas comprises a noble gas, N₂, or a combination thereof.

17. The method of claim 15, further comprising heating the substrate to a temperature between about 500° C. and about 1100° C.

18. The method of claim 17, wherein heating the substrate comprises directing radiant energy towards a device side surface thereof.

19. The method of claim 18, wherein the device side surface comprises a dielectric layer, and wherein exposing the substrate to the radical species comprises exposing the dielectric layer to the radical species.

20. The method of claim 19, wherein the second gas comprises NH₃ and the radical species comprise N, NH, NH₂, or combinations thereof.
